(19) United States
(12) Patent Application Publication
(10) Pub. No.: US 2005/0205520 A1
(43) Pub. Date: Sep. 22, 2005

(54) METHOD FOR END POINT DETECTION FOR CHEMICAL MECHANICAL POLISHING OF INTEGRATED CIRCUIT DEVICES

(75) Inventor: Meng Feng Tsai, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing International (Shanghai) Corporation, Shanghai (CN)

(21) Appl. No.: 10/831,713

(22) Filed: Apr. 23, 2004

(30) Foreign Application Priority Data
Mar. 17, 2004 (CN) 200410017138.9

(51) Int. Cl. C23F 1/00; H01L 21/302; B44C 1/22

(52) U.S. Cl. 216/86; 438/692; 216/84

(57) ABSTRACT

A method for manufacturing integrated circuit devices. The method applies a rotating polishing pad comprising a slurry and a dispersant liquid against a substantially non-even layer comprising a first material. The first material overlies a second material. The second material has one or more substantially planar regions. The method monitors a current flow driving the rotating polishing pad as portions of the substantially non-even layer are removed until a friction force increases the current flow as the substantially non-even layer becomes substantially planar in shape. The method decreases an amount of the dispersant liquid as the rotating polishing pad continues to remove portions of the first material. Additionally, the method monitors the current flow for a decrease in rate of greater than 1 amperes per second in the current flow from the increased current flow to signal an end point where one or more portions of the second material have been exposed.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention is directed integrated circuits and their processing for the manufacture of semiconductor devices. More particularly, the invention provides a method for smoothing or polishing layers used in the fabrication of semiconductor devices using a chemical mechanical polishing or planarization process, often called “CMP” or the like. But it would be recognized that the invention has a much broader range of applicability. For example, the invention can be applied to a variety of devices such as dynamic random access memory devices (DRAM), static random access memory devices (SRAM), application specific integrated circuit devices (ASIC), microprocessors and microcontrollers, Flash memory devices, and others.

Integrated circuits or “ICs” have evolved from a handful of interconnected devices fabricated on a single chip of silicon to millions of devices. Conventional integrated circuits often provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of circuits. Semiconductor devices are now being fabricated with features less than a quarter of a micron across.

Increasing circuit density has not only improved the complexity and performance of integrated circuits but has also provided lower cost parts to the consumer. An integrated circuit fabrication facility can cost hundreds of millions, or even billions, of dollars. Each fabrication facility will have a certain throughput of wafers, and each wafer will have a certain number of integrated circuits on it. Therefore, by making the individual devices of an integrated circuit smaller, more devices may be fabricated on each wafer, thus increasing the output of the fabrication facility. Making devices smaller is very challenging, as each process used in integrated circuit fabrication has a limit. That is to say, a given process typically only works down to a certain feature size, and then either the process or the device layout needs to be changed. An example of such a limit is the ability to smooth or flatten a layer in an efficient and accurate manner.

As merely an example, CMP processes are often used to smooth or flatten a layer to form structures therefrom. An example of a CMP process is described in U.S. Pat. No. 6,069,081 (the '081 patent), assigned to International Business Machines Corporation, Siemens Components, Inc., and Kabushiki Kaisha Toshiba. The '081 patent generally relates to a CMP technique using two-step processing. Such two-step process uses a first slurry until a polish stop is exposed and a second slurry until another polish stop is exposed. The '081 patent relies upon a relative complex process using multiple slurries, which are often difficult to use and control. Another example of a CMP process is described in U.S. Pat. No. 6,057,602 (the '602 patent), assigned to Micron Technology, Inc. of Boise, Id. The '602 patent illustrates a process to planarize a layer using a stratum layer as a polishing stop, among other features. Although these processes have some usefulness, it is still desired to improve chemical mechanical polishing processes.

From the above, it is seen that an improved technique for processing semiconductor devices using chemical mechanical polishing is desired.

### BRIEF SUMMARY OF THE INVENTION

According to the present invention, techniques including methods for the manufacture of semiconductor devices are provided. More particularly, the invention provides a method for smoothing or polishing layers used in the fabrication of semiconductor devices using a chemical mechanical polishing or planarization process, often called “CMP” or the like. But it would be recognized that the invention has a much broader range of applicability. For example, the invention can be applied to a variety of devices such as dynamic random access memory devices (DRAM), static random access memory devices (SRAM), application specific integrated circuit devices (ASIC), microprocessors and microcontrollers, Flash memory devices, and others.

In a specific embodiment, the invention provides a method for processing integrated circuit devices. The method applies a rotating polishing pad against a surface of a substrate while introducing a selective polishing mixture and a pre-determined surfactant species to the surface during a portion of predetermined time, e.g., time associated with a portion of the process. In a specific embodiment, the predetermined time is associated with a time interval between the first current level and the second current level. The substrate includes a trench region adjacent to a planar region, whereupon the trench region and planar region has a nitride bearing layer formed thereon to provide a liner in the trench region and protective nitride layer overlying the planar region and an overlying oxide bearing layer overlying the nitride bearing layer to define the surface of the substrate. The oxide bearing layer substantially fills the trench region and covering the nitride bearing layer. The method also maintains the rotating polishing pad against the surface of the substrate using the selective polishing mixture and the pre-determined surfactant species to remove a thickness of the oxide bearing layer from the surface of the substrate. The method also continues to maintain the rotating polishing pad against the surface of the substrate until the surface has been substantially planarized in shape whereupon a friction force between the rotating polishing pad and the surface begins to increase to indicate the planarized shape of the surface. During a vicinity of such indication of the planarized shape, the method reduces an amount of the pre-determined surfactant species to increase a friction force between the polishing pad and the surface. The method monitors an increased electric current flow driving the rotating polishing pad based upon at least the increase in the friction force between the polishing pad and the surface from the reduced amount of pre-determined surfactant species. The method then monitors a decreased current flow from the increased current flow to indicate a vicinity of an end point of the polishing process.

In an alternative specific embodiment, the invention provides a method for manufacturing integrated circuit devices. The method applies a rotating polishing pad comprising a slurry and a dispersant liquid (e.g., surfactant) against a substantially non-even layer comprising a first material. The first material overlies a second material. The second material has one or more substantially planar regions. The method monitors an electric current flow driving the rotating polishing pad as portions of the substantially non-even layer are removed until a friction force increases the current flow as the substantially non-even layer becomes substantially planar in shape. The method decreases an amount of the dispersant liquid as the rotating polishing pad continues to remove portions of the first material. Additionally, the method monitors the current flow for a decrease in rate of greater than 1 amperes per second in the current flow from the increased current flow to signal an end point where one or more portions of the second material have been exposed.

In a further alternative embodiment, the invention provides a method of using a system for chemical mechanical polishing. The system includes a variety of computer codes for carrying out functionality of the methods described herein as well as others. The system has a code directed to applying a rotating polishing pad comprising a slurry and a dispersant liquid against a substantially non-even layer comprising a first material, where the first material overlies a second material, which has one or more substantially planar regions. A code is directed to monitoring a current flow driving the rotating polishing pad as portions of the substantially non-even layer are removed until a friction force increases the current flow as the substantially non-even layer becomes substantially planar in shape. A code is directed decreasing an amount of the dispersant liquid as the rotating polishing pad continues to remove portions of the first material. The system also has a code directed to monitoring the current flow for a decrease in rate of greater than 1 amperes per second in the current flow from the increased current flow to signal an end point where one or more portions of the second material have been exposed.

Many benefits are achieved by way of the present invention over conventional techniques. For example, the present technique provides an easy to use process that relies upon conventional technology. In some embodiments, the method provides higher device yields in dies per wafer. Additionally, the method provides a process that is compatible with conventional process technology without substantial modifications to conventional equipment and processes. Preferably, the invention can be applied to a variety of applications such as memory, ASIC, microprocessor, and other devices. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified flow diagram according to an embodiment of the present invention;

FIG. 2 is a simplified plot of a method according to an embodiment of the present invention; and

FIGS. 3 through 5 illustrate simplified methods of a manufacturing process according to embodiments to the present invention

### DETAILED DESCRIPTION OF THE INVENTION

According to the present invention, techniques including methods for the manufacture of semiconductor devices are provided. More particularly, the invention provides a method for smoothing or polishing layers used in the fabrication of semiconductor devices using a chemical mechanical polishing or planarization process, often called “CMP” or the like. But it would be recognized that the invention has a much broader range of applicability. For example, the invention can be applied to a variety of devices such as dynamic random access memory devices (DRAM), static random access memory devices (SRAM), application specific integrated circuit devices (ASIC), microprocessors and microcontrollers, Flash memory devices, and others.

A method according to an embodiment of the present invention may be outlined briefly as follows:
(1) Provide semiconductor substrate (e.g., silicon wafer);
(2) Form an insulating layer (e.g., silicon nitride layer) overlying the surface of the substrate;
(3) Form one or more trench regions through the surface of the substrate and through the insulating layer overlying the in the substrate;
(4) Deposit a fill layer into the one or more trench regions to a level above the surface of the substrate to define an non-even surface;
(5) Apply a rotating polishing pad including a slurry and dispersant (e.g., surfactant) on the non-even surface of the fill layer;
(6) Maintain the rotating polishing pad against the surface of the substrate using the selective polishing mixture and the pre-determined surfactant species to remove a thickness of the oxide bearing layer from the surface of the substrate;
(7) Continue to maintain the rotating polishing pad against the surface of the substrate until the oxide bearing layer has been substantially planarized in shape whereupon a friction force between the rotating polishing pad and the surface begins to increase to indicate the planarized shape of the surface;
(9) Identify an increased current flow from the increased friction flow driving an electric motor coupled to the polishing pad;
(10) Reduce an amount of the pre-determined surfactant species during a vicinity of when the current flow has increased from the planarized shape of the surface;
(11) Monitor a decrease in current flow from the increased current flow in a vicinity of exposing the nitride layer to indicate a vicinity of an end point of the polishing process; and
(12) Perform other processes, as desired.

The above sequence of steps provides a way to process one or more layers on a semiconductor device using a chemical mechanical planarization process. These steps use an end point detection method and system to accurately determine an end point of a polishing process. Such method and system relies upon at least adjusting the surfactant species in the polishing process along with monitoring a friction force between the rotating polishing pad and surface being polished. One of ordinary skill in the art would recognize many other variations, modifications, and alternatives. Further details of the present method and system can be found throughout the specification and more particularly below.

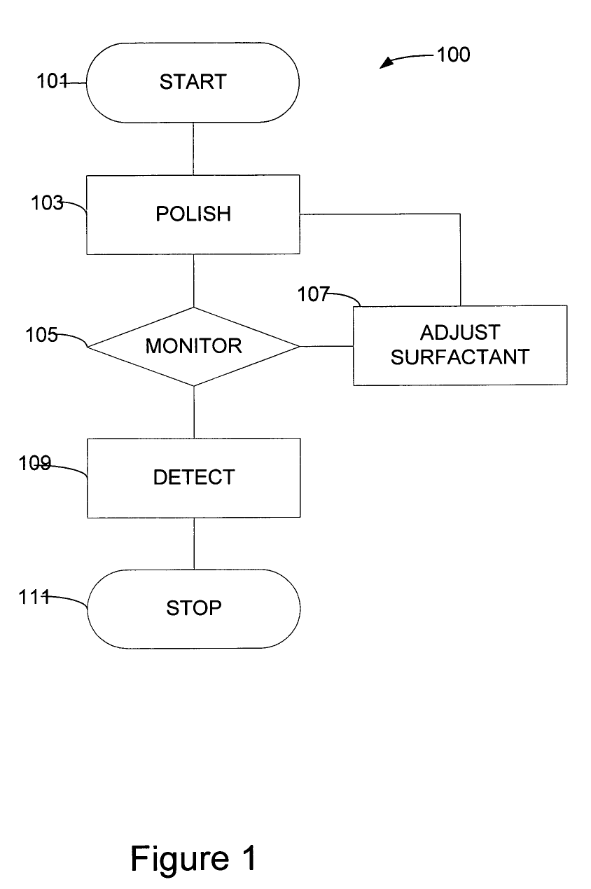

FIG. 1 is a simplified flow diagram 100 according to an embodiment of the present invention. This diagram is merely an example, which should not unduly limit the scope of the claims herein. One of ordinary skill in the art would recognize many other variations, modifications, and alternatives. As shown, the present method begins at start, step 100. The method includes a polishing process (step 103). The polishing process applies a rotating polishing pad including slurry and dispersant (e.g., surfactant) on an un-even fill layer, which is provided overlying trench regions, which have overlying nitride bearing layer. The nitride bearing layer underlies portions of the fill layer. The method maintains the rotating polishing pad against the surface of the substrate using the selective polishing mixture and the pre-determined surfactant species to remove a thickness of the fill layer from the surface of the substrate. The method continues to maintain the rotating polishing pad against the surface of the substrate until the surface has been substantially planarized in shape.

During the polishing process, the method monitors (step 105) an electric current flow of an electric motor driving the polishing pad. The current flow is monitored and checked against one or more pre-determined parameters. As merely an example, as a friction force between the rotating polishing pad and the surface begins to increase, it is indicative of a planarized shape of the surface. Preferably, the method reduces (step 107) an amount of the pre-determined surfactant species during a vicinity of when the surface has been substantially planarized. The method continues to polish while monitoring the current flow using the reduced surfactant species. That is, the method continues to remove evenly portions of the fill layer. Alternatively, another parameter indicative of the friction force between the polishing pad and the layer being polished could be monitored, depending upon the specific embodiment.

The method continues until an increased electric current flow driving the rotating polishing pad based upon at least the increase in the friction force between the polishing pad and the surface from the reduced amount of pre-determined surfactant species changes to a decreased current flow from the increased current flow to indicate a vicinity of an end point of the polishing process. Preferably, the decrease in current flow is indicative of removal of the fill material, which indicates an endpoint (step 109) of the process. The method stops at step 111.

Preferably, the invention provides a method of using a system for chemical mechanical polishing carrying out certain steps as described herein and most particularly described above. The system includes a variety of computer codes for carrying out functionality of the methods described herein as well as others. The system has a code directed to applying a rotating polishing pad comprising a slurry and a dispersant liquid against a substantially non-even layer comprising a first material, where the first material overlies a second material, which has one or more substantially planar regions. A code is directed to monitoring a current flow driving the rotating polishing pad as portions of the substantially non-even layer are removed until a friction force increases the current flow as the substantially non-even layer becomes substantially planar in shape. A code is directed decreasing an amount of the dispersant liquid as the rotating polishing pad continues to remove portions of the first material. The system also has a code directed to monitoring the current flow for a decrease in rate of greater than 1 amperes per second in the current flow from the increased current flow to signal an end point where one or more portions of the second material have been exposed. Depending upon the embodiment, the functionality herein can be carried out using computer software (or codes) running on a general purpose controller, which is coupled to a chemical mechanical polishing tool, such as those made by Applied Materials, Inc. and others.

According to the present invention, the controller includes a variety of elements such as a microprocessor based unit, a hard disk memory storage unit, input/output elements, hard wiring, and other elements. The controller also includes a display such as a flat panel display, cathode ray tube (“CRT”), and the like. The display has a graphical user interface that includes a menu. The menu or menus can correspond to a variety of process recipes that are stored on the hard drive or other memory device. The process recipes can be in the form of a computer program or programs that use computer codes in the form of software. As noted, the computer codes carryout the functionality described herein as well as others.

In a preferred embodiment, computing system includes a PentiumTM class microprocessor running Windows basedTM. operating system from Microsoft Corporation of Redmond, Wash. Many other systems, such as MacOS.TM. from Apple Corporation, running upon G3 based microprocessors, or Solaris.TM. from Sun Microsystems or UNIX running upon a SPARCstation, and the like can also be used. The present controller has computer codes that oversee the operations and perform the operations described herein as well as others. Depending upon the embodiment, there can be many other variations, alternatives and modifications. A preferred embodiment of the present invention can be briefly described throughout the present specification and more particularly below.

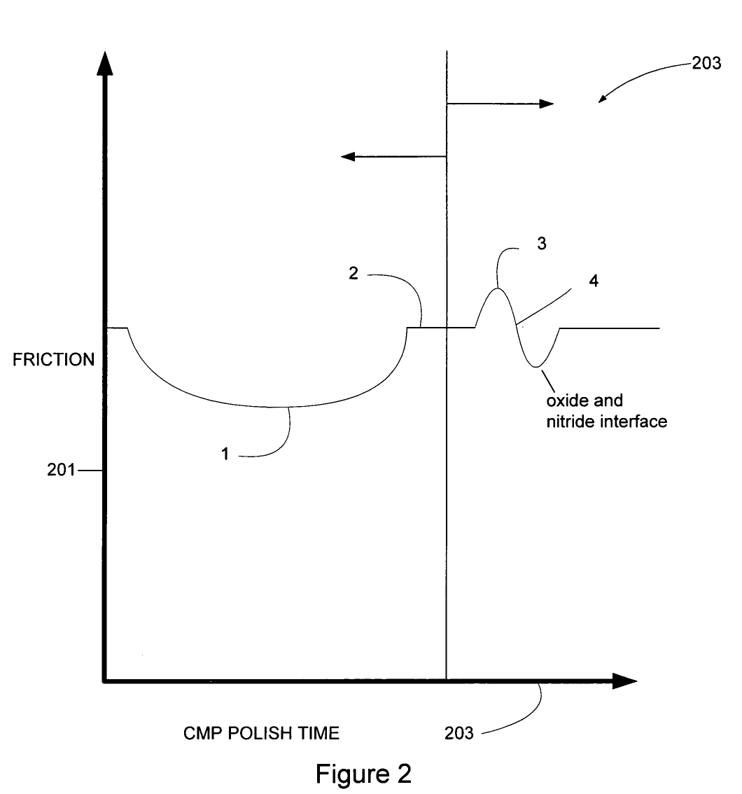

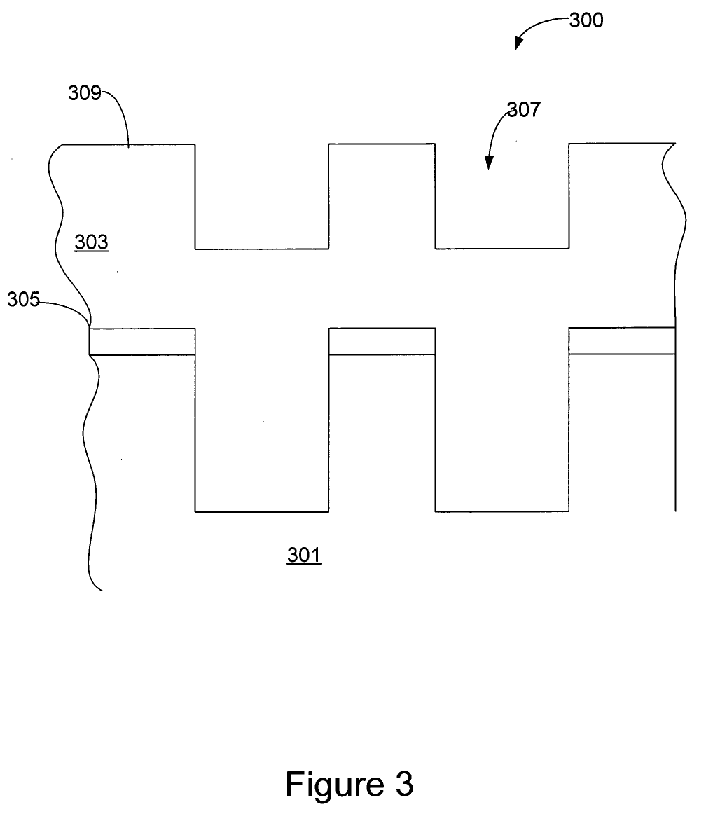

FIG. 2 is a simplified plot 200 of a method according to an embodiment of the present invention. This diagram is merely an example, which should not unduly limit the scope of the claims herein. One of ordinary skill in the art would recognize many other variations, modifications, and alternatives. As shown, the plot is provided along a first vertical axis 201, which represents friction between the rotating polishing pad and surface being polished. The plot shows friction force that increases along the axis in arbitrary units. The second axis 203 represents polishing time, which is also in arbitrary units. There are several regions in the plot, including regions 1, 2, 3, and 4, for example. This plot is illustrated in reference to cross-sectional view diagrams of partially completed semiconductor devices 300 in FIGS. 3 through 5. These diagrams are merely examples, which should not unduly limit the scope of the claims herein. One of ordinary skill in the art would recognize many other variations, modifications, and alternatives.

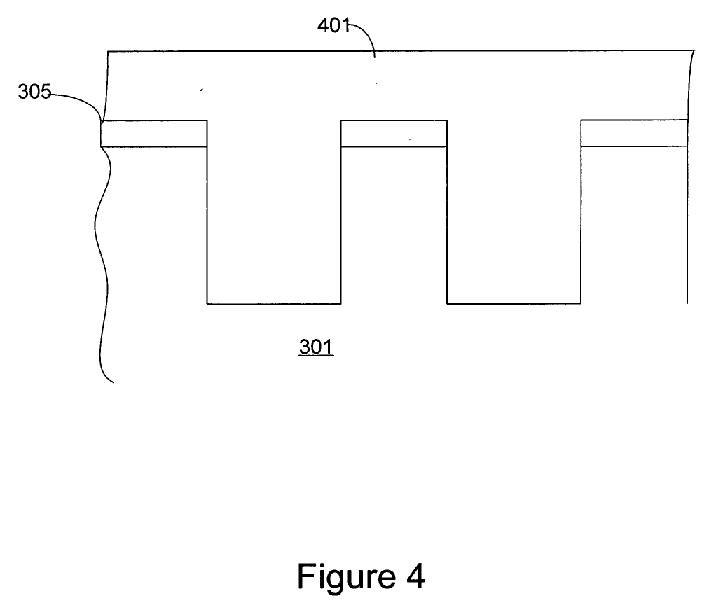

As shown, the method applies a rotating polishing pad including slurry and dispersant (e.g., surfactant) on an un-even fill layer 309, which is provided overlying trench regions 307, which have overlying nitride bearing layer 305 (See region 1 and 2 in plot for corresponding friction and polishing time relationships). The fill layer is often a dielectric material 303, e.g., silicon dioxide. The trench regions are formed on substrate 301, which is commonly silicon or other starting material, e.g., silicon on insulator, an epitaxial silicon layer, and the like. The method maintains the rotating polishing pad against the surface of the substrate using the selective polishing mixture and the pre-determined surfactant species to remove a thickness of the fill layer from the surface of the substrate. The method continues to maintain the rotating polishing pad against the surface of the substrate until the surface has been substantially planarized in shape 401, as shown by the simplified diagram of FIG. 4. As also shown, region “2” in the plot is illustrated. Such region 2 illustrates that the friction force increases from the increased surface area of the planarized fill layer 401.

In a specific embodiment, the method monitors a friction force between the rotating polishing pad and the layer being polished using a current flow of a motor driving the polishing pad. The current flow is monitored and checked against one or more pre-determined parameters. As merely an example, as the friction force between the rotating polishing pad and the surface begins to increase, it is indicative of a planarized shape of the surface. Preferably, the method reduces an amount of the pre-determined surfactant species during a vicinity of when the fill layer has been planarized. The method continues to polish the fill layer evenly (e.g., without any uneven surface regions) while monitoring the current flow. Alternatively, another parameter indicative of the friction force between the polishing pad and the layer being polished could be monitored, depending upon the specific embodiment.

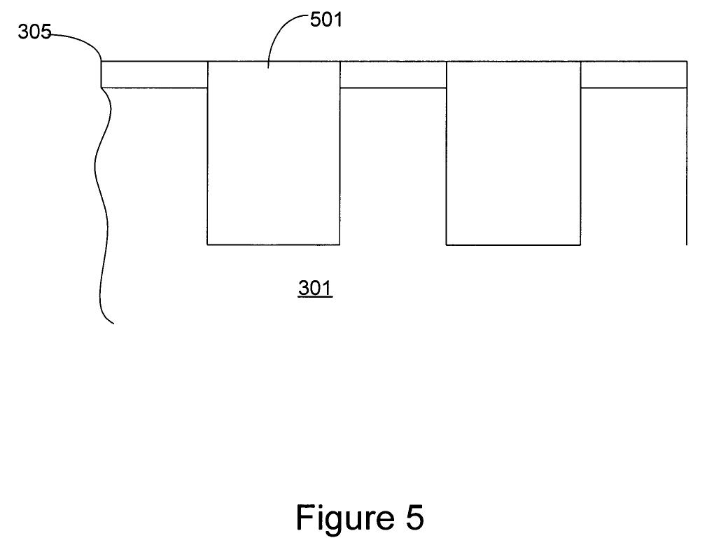

The method continues until the increased electric current flow driving the rotating polishing pad based upon at least the increase in the friction force between the polishing pad and the surface from the reduced amount of pre-determined surfactant species changes to a decreased current flow (See region 4) from the increased current flow to indicate a vicinity of an end point of the polishing process. Here, portions of the nitride layer are exposed and the nitride layer has a surface that is substantially even with the surface of the fill layer. Preferably, the decrease in current flow is indicative of a planarized fill material have its surface substantially parallel with the surface of the nitride layer, which indicates an endpoint (step 109) of the process, as shown in FIG. 5. As shown, the fill layer is substantially even with the nitride layer to provide a planarized surface region. Depending upon the embodiment, there can be many other variations, alternatives and modifications.

Experimental Results:

To prove the principle and operation of the present invention, I performed experiments using conventional semiconductor tools. In our experiment, I fabricated silicon wafers using the structures similar to the Figures above. Such structures included trench isolation regions, which were lined with a silicon nitride liner and have overlying oxide. The oxide is CVD deposited using a single chamber tool manufactured by Applied Materials, Inc. of Santa Clara, Calif. The silicon nitride liner was thermally deposited using a furnace manufactured by Tokyo Electron Limited (TEL) of Japan.

For the polishing process, I used a FREX-200 chemical mechanical polishing tool manufactured by Ebara, Ltd. of Japan. Such tool was used for application to certain layers on the trench isolation regions on the silicon wafer. A selective polishing mixture of CeO₂ based chemistry was used. An example of such chemistry is called dish less slurry (“DLS”) manufactured by Hitachi Chemical, Ltd. A dispersant used with the slurry was TK 75 manufactured by Kao of Japan. The slurry and dispersant were mixed together in the process. An overall process flow used is provided as follows:
(1) Apply a rotating polishing pad including a slurry at a concentration of 0.5% weight and dispersant at a concentration of 4.7% vol on the non-even surface of the fill layer;
(2) Maintain the rotating polishing pad at 100 revolutions per minute and force of 392 hPa against the surface of the substrate using the selective polishing mixture and the pre-determined surfactant species to remove a thickness (i.e., 0.7 microns) of the oxide bearing layer from the surface of the substrate;
(3) Continue to maintain the rotating polishing pad against the surface of the substrate until the oxide bearing layer has been substantially planarized in shape whereupon a friction force between the rotating polishing pad and the surface begins to increase by about 7 A to indicate the planarized shape of the surface;
(4) Identify an increased current flow of about 15 A from the increased friction flow driving an electric motor coupled to the polishing pad;
(5) Reduce an amount of the pre-determined surfactant species to about 1.6% vol concentration during a vicinity of when the current flow has increased from the planarized shape of the surface; and
(6) Monitor a decrease in current flow of about 3 A from the increased current flow in a vicinity of exposing the nitride layer to indicate a vicinity of an end point of the polishing process.

As should be know, the above sequence of steps is merely an example and should not unduly limit the scope of the claims herein. One of ordinary skill in the art would recognize many other variations, modifications, and variations. Based upon this experiment I provided the simplified diagram of FIG. 2, which should also not be limiting in any manner but merely provided for illustration purposes.

It is also understood that the examples and embodiments described herein are for illustrative purposes only and that various modifications or changes in light thereof will be suggested to persons skilled in the art and are to be included within the spirit and purview of this application and scope of the appended claims.

1. A method for processing integrated circuit devices, the method comprising:
applying a rotating polishing pad against a surface of a substrate while introducing a selective polishing mixture and a pre-determined surfactant species to the surface during a portion of predetermined time, the substrate including a trench region adjacent to a planar region, whereupon the trench region and planar region having a nitride bearing layer formed thereon to provide a liner in the trench region and protective nitride layer overlying the planar region and an overlying oxide bearing layer overlying the nitride bearing layer to define the surface of the substrate, the oxide bearing layer substantially filling the trench region and covering the nitride bearing layer;
maintaining the rotating polishing pad against the surface of the substrate using the selective polishing mixture and the pre-determined surfactant species to remove a thickness of the oxide bearing layer from the surface of the substrate;
continuing to maintain the rotating polishing pad against the surface of the substrate until the surface has been substantially planarized in shape whereupon a friction force between the rotating polishing pad and the surface begins to increase to indicate the planarized shape of the surface;
reducing an amount of the pre-determined surfactant species during a vicinity of the surface that has been substantially planarized;
monitoring an increased electric current flow driving the rotating polishing pad based upon at least the increase in the friction force between the polishing pad and the surface from the reduced amount of pre-determined surfactant species; and
monitoring a decreased current flow from the increased current flow to indicate a vicinity of an end point of the polishing process after the amount of pre-determined surfactant species has been reduced.

2. The method of claim 1 wherein the electric current flow is reduced from a first current level to a second current level within a predetermined time.

3. The method of claim 2 wherein the predetermined time is associated with a time interval between the first current level and the second current level.

4. The method of claim 1 further comprising removing the rotating polishing pad from the surface of the substrate based upon the end-point.

5. The method of claim 1 wherein the oxide bearing layer is high density plasma oxide or atmospheric chemical vapor deposition oxide.

6. The method of claim 1 wherein the nitride bearing layer is silicon nitride.

7. The method of claim 1 wherein the trench region is form a STI structure.

8. The method of claim 1 wherein the selective polishing mixture using CeO₂.

9. The method of claim 1 wherein the pre-determined surfactant species is TK 75 manufactured by Kao of Japan.

10. The method of claim 1 wherein the polishing pad rotates at about 100 revolutions per minute.

11. A method for manufacturing integrated circuit devices, the method comprising:
applying a rotating polishing pad comprising a slurry and a dispersant liquid against a substantially non-even layer comprising a first material, the first material overlying a second material, the second material having one or more substantially planar regions;
monitoring a current flow driving the rotating polishing pad as portions of the substantially non-even layer are removed until a friction force increases the current flow as the substantially non-even layer becomes substantially planar in shape;
decreasing an amount of the dispersant liquid as the rotating polishing pad continues to remove portions of the first material; and
monitoring the current flow for a decrease in rate of greater than 1 amperes per second in the current flow from the increased current flow to signal an end point where one or more portions of the second material have been exposed.

12. The method of claim 11 wherein the rate is greater than 5 amperes per second.

13. The method of claim 11 wherein the one or more substantially planar regions is disposed adjacent to trench regions, the trench regions being filled by the first material.

14. The method of claim 11 wherein the first material is silicon dioxide.

15. The method of claim 11 wherein the second material is silicon nitride.

16. The method of claim 11 wherein the substantially non-even layer is a deposited layer.

17. A method of using a system for chemical mechanical polishing, the system comprising:
a code directed to applying a rotating polishing pad comprising a slurry and a dispersant liquid against a substantially non-even layer comprising a first material, the first material overlying a second material, the second material having one or more substantially planar regions;
a code directed to monitoring a current flow driving the rotating polishing pad as portions of the substantially non-even layer are removed until a friction force increases the current flow as the substantially non-even layer becomes substantially planar in shape;
a code directed decreasing an amount of the dispersant liquid as the rotating polishing pad continues to remove portions of the first material; and
a code directed to monitoring the current flow for a decrease in rate of greater than 1 amperes per second in the current flow from the increased current flow to signal an end point where one or more portions of the second material have been exposed.
